(19) United States
(12) Patent Application Publication
(10) Pub. No.: US 2014/0358460 A1
(43) Pub. Date: Dec. 4, 2014

(54) ELECTRIC VEHICLE AND METHOD FOR CONTROLLING SAME

(71) Applicant: Young Hwan Lee, Incheon (KR)

(72) Inventor: Young Hwan Lee, Incheon (KR)

(73) Assignee: LG Electronics Inc., Seoul (KR)

(21) Appl. No.: 14/365,770

(22) PCT Filed: Dec. 14, 2012
(86) PCT No.: PCT/KR2012/010952

§ 371 Date: Jun. 16, 2014

(30) Foreign Application Priority Data
Dec. 16, 2011 (KR) 10-2011-0136483

(51) Int. Cl. G01R 31/36; B60L 11/18; G01R 19/25

(52) U.S. Cl. CPC G01R 31/362; G01R 19/2513; B60L 11/1861
USPC 702/63

(57) ABSTRACT

The present invention relates to an electric vehicle and to a method for controlling same. The electric vehicle according to the present invention comprises: a battery for storing electrical energy; a cluster for calculating the final state of charge (SOC) of the battery and indicating the result of the calculation; a battery management system for transmitting raw data of the SOC of the battery to the cluster at a predetermined interval; and a motor control unit for measuring the power consumption of the motor at predetermined interval and transmitting the measured power consumption to the cluster. The cluster includes a cluster control unit for calculating the final SOC using the raw data of the SOC of the battery and the power consumption of the motor, and a cluster indication unit for indicating the final SOC.

### TECHNICAL FIELD

The present invention relates to an electric vehicle and a method of controlling the same, and more particularly, to an electric vehicle and a method of controlling the same, for calculating and displaying a state of charge (SOC) of a vehicle battery.

### BACKGROUND ART

Research has been actively conducted into electric vehicles in terms of alternatives that are most likely to address conventional vehicle pollution and energy problems.

An electric vehicle (EV) is a vehicle that drives an alternating current (AC) or direct current (DC) motor using battery power to obtain power and is largely classified into a battery powered electric vehicle and a hybrid electric vehicle. The battery powered electric vehicle drives a motor using battery power and is charged when battery power is entirely consumed. The hybrid electric vehicle is moved by driving an engine to generate electricity and to charge a battery and driving an electric motor using the electricity.

The hybrid electric vehicle may be classified into a series-type hybrid electric vehicle and a parallel-type hybrid electric vehicle. The series-type hybrid electric vehicle is always driven by a motor by converting mechanical energy output from an engine into electrical energy via a generator and supplying the electrical energy into a battery or the motor and is interpreted as the concept obtained by adding an engine and a generator to a conventional electric vehicle for improvement in mileage. The parallel-type hybrid electric vehicle uses two power sources for moving the vehicle via only battery power or only an engine (gasoline or diesel) and is driven using both the engine and the motor according to a driving condition.

Recently, motor/control technology has been gradually developed and high power of small systems with high efficiency has been developed. As a DC motor is converted into an AC motor, power performance (acceleration performance and high speed) of electric vehicles is remarkably increased. Accordingly, electric vehicles have reached a level equivalent to gasoline vehicles. As a motor of high power and high rate of rotation have been achieved, the motor has become lightweight and small and has been reduced in weight on board or volume.

The electric vehicle calculates and displays a battery state of charge (SOC). In this regard, there are many control parameters that are varied according to a battery state or environment. Thus it is difficult to accurately calculate an actual battery SOC and variability of the battery SOC is serious due to accumulated errors over time. Due to this rapid change in an SOC, a driver feels an anxiety.

### DISCLOSURE

### Technical Problem

It is an aspect of the present invention to provide an electric vehicle and a method of controlling the same, for calculating a state of charge (SOC) of a battery using an SOC according to power consumption of a motor so as to consider residual capacity that is actually used or available by the motor, thereby enhancing accuracy of the battery SOC and enhancing reliability of the battery SOC.

### Technical Solution

In accordance with one aspect of the present invention, an electric battery includes a battery for storing electrical energy, a cluster for calculating and displaying a final state of charge (SOC) of the battery, a battery management system for transmitting raw data of an SOC of the battery to the cluster every predetermine time, and a motor controller for measuring power consumption of a motor and transmitting the power consumption to the cluster every predetermine time, wherein the cluster includes a cluster controller for calculating the final SOC using the raw data of the SOC of the battery and the power consumption of the motor, and a cluster display for displaying the final SOC.

In accordance with another aspect of the present invention, a method of controlling an electric vehicle includes detecting raw data of a state of charge (SOC) of a battery every predetermined time, measuring power consumption of a motor every predetermined time, calculating a final SOC using the raw data of the SOC of the battery and the power consumption of the motor, and displaying the final SOC.

### Advantageous Effects

In an electric vehicle and a method of controlling the same, a final battery state of charge (SOC) may be calculated using raw data indicating a battery SOC measured by a cluster controller and an SOC according to power consumption of a motor.

Accordingly, reliability of a battery SOC may be ensured and stability may be provided to a driver.

### DESCRIPTION OF DRAWINGS

FIG. 1 is a schematic diagram illustrating an internal structure of an electric vehicle according to an embodiment of the present invention.

FIG. 2 is a schematic diagram illustrating the flow of calculation of an SOC of an electric vehicle according to an embodiment of the present invention.

FIG. 3 is a graph illustrating a battery SOC according to a mileage of an electric vehicle according to an embodiment of the present invention.

### MODE FOR INVENTION

Hereinafter, the present invention will be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art. Like reference numerals in the drawings denote like elements.

Hereinafter, an electric vehicle and a method of controlling the same according to embodiments of the present invention will be described with reference to the attached drawings.

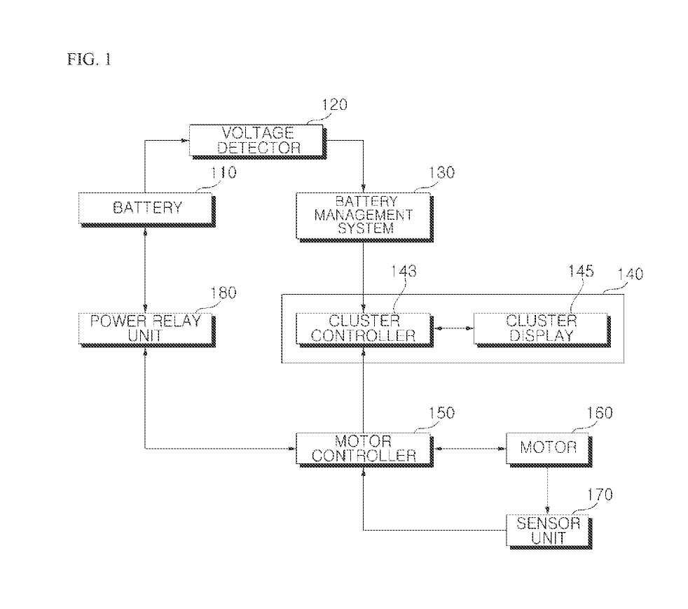

FIG. 1 is a schematic diagram illustrating an internal structure of an electric vehicle according to an embodiment of the present invention.

Referring to FIG. 1, the electric vehicle according to an embodiment of the present invention includes a battery 110, a voltage detector 120, a battery management system (BMS) 130, a cluster 140, a motor controller 150, a motor 160, a sensor unit 170, and a power relay unit (PRA) 180.

The electric vehicle includes the battery 110, operates using power stored in the battery 110, and charges the battery 110 included in the electric vehicle, which receives power from an external source such as a predetermined charging station, vehicle charging equipment, or the home.

The battery 110 includes a plurality of battery cells and stores high voltage electric energy. In this case, the electric vehicle further includes the BMS 130 that controls charging of the battery 110, determines residual capacity and the need to charge the battery 110, and performs management for supply of charged current stored in the battery 110 to each unit of the electric vehicle.

During charging and use of the battery 110, the BMS 130 controls the battery 110 such that a voltage difference between cells in the battery 110 is uniformly maintained and the battery 110 is not overcharged or over discharged, thereby extending lifetime of the battery 110.

The voltage detector 120 detects an output voltage level of the battery 110 and checks a battery state of charge (SOC). In addition, the voltage detector 120 may output the detected voltage level and transmit information about the detected voltage level to the BMS 130.

The BMS 130 may output a current SOC of the battery 110 and a battery voltage to a cluster controller 143.

The PRA 180 includes a sensor and a plurality of relays for high voltage switching and supplies or interrupts high voltage of operating power supplied from the battery 110 to or from the motor controller 150. In this case, relays of the PRA 180 operate according to a control command of a vehicle controller (not shown).

When an engine of the electric vehicle is turned on or turned off, the PRA 180 switches a plurality of relays included in the electric vehicle in a predetermined order according to the control command of a vehicle controller (not shown) so as to supply high voltage of operating power stored in the battery 110 to each unit of the electric vehicle.

The PRA 180 may interrupt power supplied to the motor controller 150 from the battery 110 to interrupt power supplied to the motor 160. Accordingly, the motor 160 is stopped and thus the electric vehicle is also stopped.

The motor controller 150 generates a control signal for driving at least one motor 160 connected to the motor controller 150 and generates a predetermined signal for motor control and supplies the signal to the motor 160. In this case, the motor controller 150 may include an inverter (not shown) and a converter (not shown) and control the inverter or the converter to control driving of the motor 160.

The sensor unit 170 detects signals generated during vehicle driving or predetermined operations and inputs the signals to a vehicle controller (not shown). The sensor unit 170 includes a plurality of sensors installed inside and outside the electric vehicle. In this case, types of the sensors may also differ according to installment position. The sensor unit 170 includes a wheel sensor for detection of wheel velocity for torque calculation and a slope sensor for detection of vehicle inclination.

The sensor unit 170 may include a plurality of sensors, measure input current of the motor 160 and a rotor angle of the motor 160, and transmit the measured values to the motor controller 150.

The cluster 140 may include the cluster controller 143 and a cluster display 145.

The cluster controller 143 may calculate a battery SOC using data input from the motor controller 150 or the BMS 130. In this case, the data may be raw data, of an SOC measured in a battery, a finally charged SOC amount, and power consumption of the motor 160.

The cluster display 145 may externally output information during an current state operation of the electric vehicle, for example, a mileage, velocity, temperature, etc. The cluster display 145 may include a display for displaying information, a speaker for outputting music, sound effects, and warning sounds, and units for outputting various statuses, etc. so as to inform a driver of current vehicle information.

In addition, the cluster display 145 may output a final SOC input from the cluster controller 143 to display a current battery state to the driver.

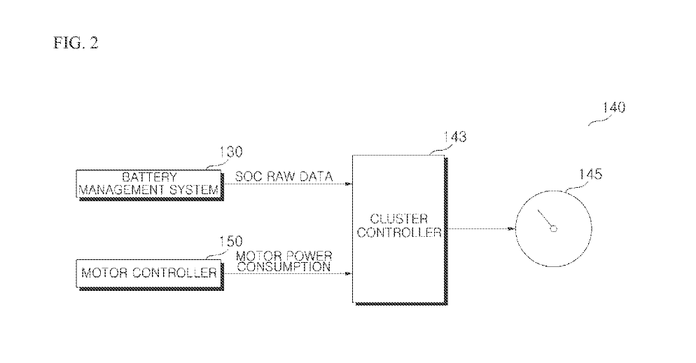

FIG. 2 is a schematic diagram illustrating the flow of calculation of an SOC of an electric vehicle according to an embodiment of the present invention.

Referring to FIG. 2, the cluster controller 143 may receive data from the BMS 130 and the motor controller 150 and calculate a battery SOC, as described with reference to FIG. 1.

The battery SOC is a value indicating a current charging value of a battery and indicates a percentage of a current holding capacity to maximum available capacity of the battery. The cluster controller 143 does not display the battery SOC as raw data of an SCO measured in the battery or a value obtained by correcting the raw data of the SOC only and calculates the SOC of the battery in consideration of power consumption of a motor in order to enhance accuracy. In this case, the battery SOC is calculated as follows.

calSOC(t)=chargSOC−accSOC(t) [Equation 1]

Equation 1 above represents a procedure for calculation of a battery SOC according to power consumption of the motor 160. Here, calSOC(t) represents an SOC according to motor power consumption, chargSOC represents an SOC of a finally charged battery of an electric vehicle, and accSOC(t) is a consumed amount of an accumulated SOC according to motor power consumption. In this case, accSOC(t) is obtained by multiplying accPwr(t) by 100/30600 and indicates accumulated power consumption that is calculated using power consumption.

FSOC(t)=FSOC(t−1)−(FSOC(t−1)−rawSOC(t))*0.1 [Equation 2]

Equation 2 above represents a procedure for calculation of a battery SOC obtained by correcting raw data of a battery SOC measured in the battery, which is received from a BMS. Here, ESOC(t) represents a battery SOC corrected at time t and FSOC(t−1) represents a battery SCO corrected at (t−1). In addition, rawSOC(t) represents raw battery of a battery SCO that is calculated based on an output voltage measured at time t by the voltage detector 120.

SOC(t)=calSOC(t)*FSOC(t)/100+FSOC(t)*(1−FSOC(t))/100 [Equation 3]

Equation 3 above represents a procedure for calculation of a final battery SOC. Here, calSOC(t) is the value calculated according to Equation 1 above and FSOC(t) is the value calculated according to Equation 2 above. A final battery SOC(t) may be calculated by inserting the values into Equation 3 above.

The cluster display 145 may output the final battery SOC(t) calculated by the cluster controller 143. The cluster display 145 may display the final battery SOC(t) as a number or display the final battery SOC(t) using a needle indicating gradations.

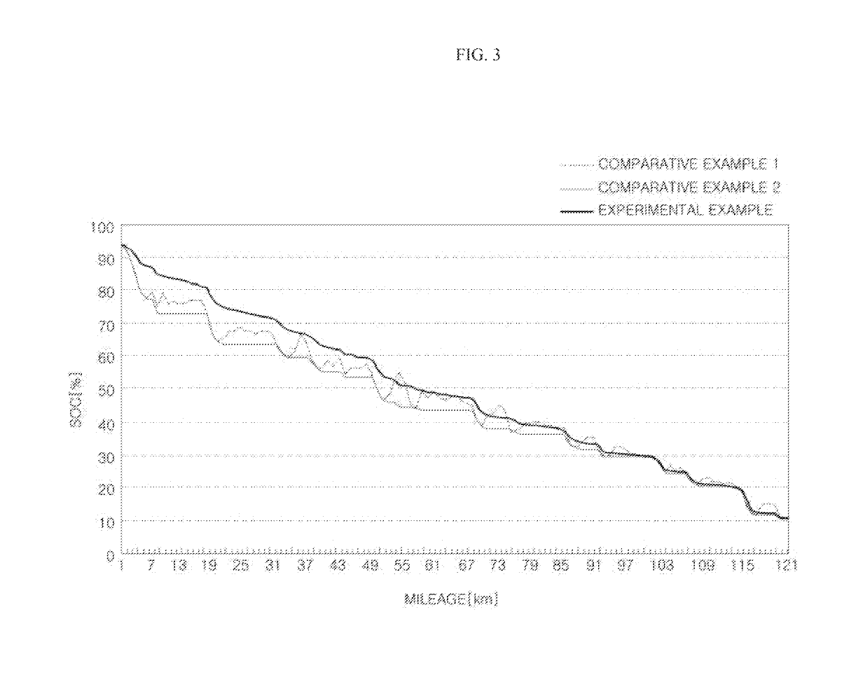

FIG. 3 is a graph illustrating a battery SOC according to a mileage of an electric vehicle according to an embodiment of the present invention.

Referring to FIG. 3, a plot of Comparative Example 1 indicates raw data, of an SOC measured by the battery 110. A plot of Comparative Example 2 indicates a corrected battery SOC obtained by correcting the raw data of the SOC. A plot of Experimental Example indicates a final SOC in consideration of the corrected battery SOC and an SOC according to motor power consumption.

Comparing Experimental Example with Comparative Examples 1 and 2, a battery SOC display on the cluster display 145 rapidly changes in Comparative Examples 1 and 2. In particular, Comparative Example 1 indicates raw data of a measured SOC and the accuracy of the raw data is degraded due to high possibility of error. Comparative Example 2 is an SOC obtained by measuring raw data of a measured SOC one time. However, in this case, an amount that is actually used or available by the motor 160 may not be accurately calculated, thereby degrading the accuracy of the SOC.

On the other hand, as seen from the plot of Experimental Example, a battery SOC stably changes and is displayed. Here, the battery SOC is a value obtained in consideration of a consumed SOC according to motor power consumption, thereby enhancing the accuracy of a battery SOC.

Accordingly, in an electric vehicle and a method of controlling the same according to embodiments of the present invention, a battery SOC may be calculated using an SOC according to motor power consumption as well as raw data of the battery SOC, and thus, a more accurate battery SOC may be indicated to a driver than raw data of a measured SOC or a battery SOC corrected using the raw data. In addition, reliability of an SOC may be provided to the driver using the stable value, thereby enhancing entire stability of an electric vehicle.

Although the embodiments of the present invention have been disclosed for illustrative purposes, those skilled in the art will appreciate that various modifications, additions and substitutions are possible, without departing from the scope and spirit of the invention as disclosed in the accompanying claims.

1. An electric battery comprising:
a battery for storing electrical energy;
a cluster for calculating and displaying a final state of charge (SOC) of the battery;
a battery management system for transmitting raw data of an SOC of the battery to the cluster every predetermine time; and
a motor controller for measuring power consumption of a motor and transmitting the power consumption to the cluster every predetermine time,
wherein the cluster comprises:
a cluster controller for calculating the final SOC using the raw data of the SOC of the battery and the power consumption of the motor; and
a cluster display for displaying the final SOC.

2. The electric battery according to claim 1, further comprising a voltage detector for detecting an output voltage of the battery and transmitting the output voltage to the battery management system.

3. The electric battery according to claim 1, wherein the cluster controller calculates a corrected SOC using the raw data of the SOC, calculates an SOC according to the power consumption of the motor using the power consumption of the motor, and calculates the final SOC using the corrected SOC and an SOC according to the power consumption of the motor.

4. The electric battery according to claim 3, wherein the cluster controller calculates the corrected SOC according to Equation (1) below:
FSOC(t)=FSOC(t−1)−(FSOC(t−1)−rawSOC(t))*0.1 Equation (1); and
the FSOC is the corrected SOC, and rawSOC is the raw data of the SOC.

5. The electric battery according to claim 4, wherein the cluster controller calculates the final SOC according to Equation (2) below:
(chargSOC−accSOC(t))*FSOC(t)/100+FSOC(t)*(1−FSOC(t))/100 Equation (2); and
the chargSOC is a final charged battery amount (%), and the accSOC is an SOC according to power consumption.

6. A method of controlling an electric vehicle, the method comprising:
detecting raw data of a state of charge (SOC) of a battery every predetermined time;
measuring power consumption of a motor every predetermined time;
calculating a final SOC using the raw data of the SOC of the battery and the power consumption of the motor; and
displaying the final SOC.

7. The method according to claim 6, wherein the calculating of the final SOC comprises:
calculating a corrected SOC using the raw data of the battery SOC;
calculating an SOC according to the power consumption of the motor using the power consumption of the motor; and
calculating the final SOC using the corrected SOC and an SOC according to the power consumption of the motor.

8. The method according to claim 7, wherein the corrected SOC is calculated according to Equation (1) below:
FSOC(t)=FSOC(t−1)−(rawSOC(t))*0.1 Equation (1); and
the FSOC is the corrected SOC, and rawSOC is the raw data of the SOC.

9. The method according to claim 8, wherein the final SOC is calculated according to Equation (2) below:
(chargSOC−accSOC(t))*FSOC(t)/100+FSOC(t)*(1-FSOC(t)/100 Equation (2); and
the chargSOC is a final charged battery amount (%), and the accSOC is an SOC according to power consumption.
